(19) United States
(12) Patent Application Publication
(10) Pub. No.: US 2025/0233101 A1
(43) Pub. Date: Jul. 17, 2025

(54) ELECTRONIC COMPONENT REWORK METHOD AND DEVICE

(71) Applicant: Innostar Service Inc., Taichung City (TW)

(72) Inventor: Chih-Meng WU, Taichung City (TW)

(21) Appl. No.: 18/970,397

(22) Filed: Dec. 5, 2024

(30) Foreign Application Priority Data
Jan. 16, 2024 (TW) 113101712

(51) Int. Cl. H01L 23/00

(52) U.S. Cl. CPC H01L 24/742; H01L 24/11; H01L 2224/11334; H01L 2224/742; H01L 2224/749

(57) ABSTRACT

An electronic component rework method including: driving an actuating device to open a plurality of holes of a gate to allow electronic components to pass through downward; driving a pneumatic control device to perform a negative pressure operation on a pneumatic channel of a tubular part to draw a to-be-outputted electronic component into the tubular part and hold the to-be-outputted electronic component therein; and moving the tubular part to above a target contact pad of a substrate, driving the pneumatic control device to terminate the negative pressure operation and then perform a blowing operation to send downward the to-be-outputted electronic component and prevent another electronic component from moving downward through the tubular part.

### BACKGROUND OF THE INVENTION

### Field of the Invention

The invention relates to rework of electronic components, especially to a method of reworking electronic components formed on a chip.

### Description of the Related Art

Semiconductor packaging technology generally includes an automated soldering process for attaching metal pins to multiple contact pads of a chip, where the chip can be one of many chips formed on a wafer, or a chip cut from a wafer, and the metal pins can be made of copper.

In addition, after the completion of the automated soldering process, if some contact pads of the chip are found not attached with metal pins or attached with defective metal pins, a manual rework process is generally required.

However, the manual rework process is inefficient and may damage the chip if the operator is not skilled enough.

As a result, a novel electronic component rework scheme is needed in the field.

### SUMMARY OF THE INVENTION

One objective of the invention is to provide an electronic component rework method, which can efficiently sift out an electronic component for rework usage from a plurality of electronic components by means of a sifting and guiding structure.

Another objective of the invention is to provide an electronic component rework method, which can attract the electronic component for rework usage into a tubular part and hold it in place therein by a negative pressure operation, and after the tubular part is moved to above a target contact pad on a substrate, can use a blowing operation to push the electronic component for rework usage downward and prevent another electronic component from moving downward from the top of the tubular part at the same time.

Another objective of the invention is to provide an electronic component rework device, which can efficiently sift out an electronic component for rework usage from a plurality of electronic components by means of the aforementioned electronic component rework method.

Still another objective of the invention is to provide an electronic component rework device, which, by means of the aforementioned electronic component rework method, can attract the electronic component for rework usage into a tubular part and hold it in place therein by a negative pressure operation, and when the tubular part is moved to above a target contact pad on a substrate, can use a blowing operation to push the electronic component for rework usage downward and prevent another electronic component from moving downward from the top of the tubular part at the same time.

To attain the above objectives, an electronic component rework device is proposed, which includes:
a body having a feeding part, a tapering part, and a tubular part sequentially connected, the feeding part having a feeding opening for receiving a plurality of electronic components;
a sieve, which is transversely disposed in the feeding part for sifting out defective ones of the electronic components and contaminating material attached to the electronic components;
a gate, which is transversely disposed below the sieve in the feeding part for allowing the electronic components to fall downward when the gate is in an open state and preventing the electronic components from falling downward when the gate is in a closed state;
a stopper, which is provided in the tapering part to prevent excessive accumulation of the electronic components at an inlet of the tubular part; and
a pneumatic channel located on an upper side of an outer wall of the tubular part and connected with an inner cavity of the tubular part for carrying out a pneumatic control procedure, the pneumatic control procedure including: performing a negative pressure operation to draw a to-be-outputted electronic component of the electronic components into the tubular part and hold the to-be-outputted electronic component therein; and after the tubular part is moved to above a target contact pad of a substrate, driving the pneumatic control device to terminate the negative pressure operation and then perform a blowing operation to provide a downward air flow to send downward the to-be-outputted electronic component and provide an upward air flow to prevent another one of the electronic components from moving downward from the upper end of the tubular part.

In one embodiment, the body is mounted on a vibration platform and the vibration platform has an electrically controlled vibration device.

In one embodiment, the gate has a plurality of closable holes controlled to be open or closed by an actuating device.

In one embodiment, the tubular part has at least one pressure relief hole formed near a lower end thereof for slowing down a falling speed of the to-be-outputted electronic component.

In one embodiment, the electronic components are copper pins.

In one embodiment, the distance from the stopper to the inlet of the tubular part is two to four times the length of the electronic component.

In one embodiment, the distance from the inlet of the tubular part to the pneumatic channel is one to three times the length of the electronic component.

To attain the above objectives, the invention further proposes an electronic component rework method, which is realized by using a control circuit and the electronic component rework device mentioned above, the method including:
the control circuit driving a feeding device to feed a plurality of electronic components into the opening of the feeding part;
the control circuit driving an actuating device to open the holes of the gate to allow the electronic components to pass through downward;
the control circuit driving a pneumatic control device to performing a negative pressure operation to draw a to-be-outputted electronic component of the electronic components into the tubular part and hold the to-be-outputted electronic component therein; and
the control circuit driving a robotic arm to move the electronic component rework device to a location where the tubular part is above a target contact pad of a substrate, and then driving the pneumatic control device to terminate the negative pressure operation, and then perform a blowing operation to provide a downward air flow to send downward the to-be-outputted electronic component and provide an upward air flow to prevent another one of the electronic components from moving downward from the upper end of the tubular part.

In one embodiment, the electronic component rework device is mounted on a vibration platform having an electrically controlled vibration device, and the method further includes: the control circuit driving the electrically controlled vibration device to expedite the electronic components falling downward.

In one embodiment, the holes of the gate are controlled to be open or closed by the actuating device.

In one embodiment, the tubular part has at least one pressure relief hole formed near a lower end thereof for slowing down a falling speed of the to-be-outputted electronic component.

In one embodiment, the electronic components are copper pins.

In one embodiment, the distance from the stopper to the inlet of the tubular part is two to four times the length of the electronic component.

In one embodiment, the distance from the inlet of the tubular part to the pneumatic channel is one to three times the length of the electronic component.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 illustrates a block diagram of a rework apparatus including an electronic component rework device of the invention;

FIG. 2 illustrates a schematic diagram of the electronic component rework device according to one embodiment of the invention;

FIGS. 3a and 3b illustrate scenarios before and after the pneumatic control device of the rework apparatus of FIG. 1 performs a negative pressure operation on the pneumatic channel of the electronic component rework device;

FIG. 3c is for illustration of using the pneumatic control device of the rework apparatus of FIG. 1 to perform a blowing operation on the pneumatic channel after terminating the negative pressure operation; and

FIG. 4 illustrates a flow chart of an electronic component rework method according to one embodiment of the invention.

### DETAILED DESCRIPTION OF THE PREFERRED EMBODIMENTS

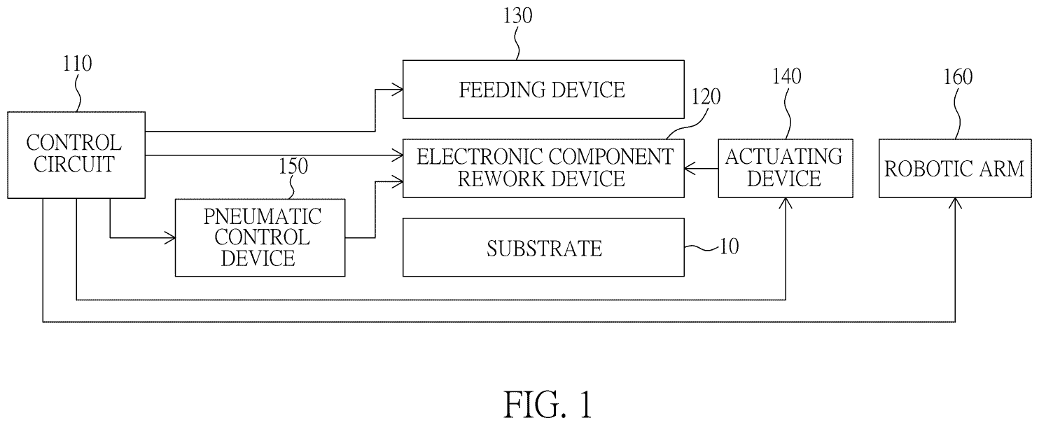

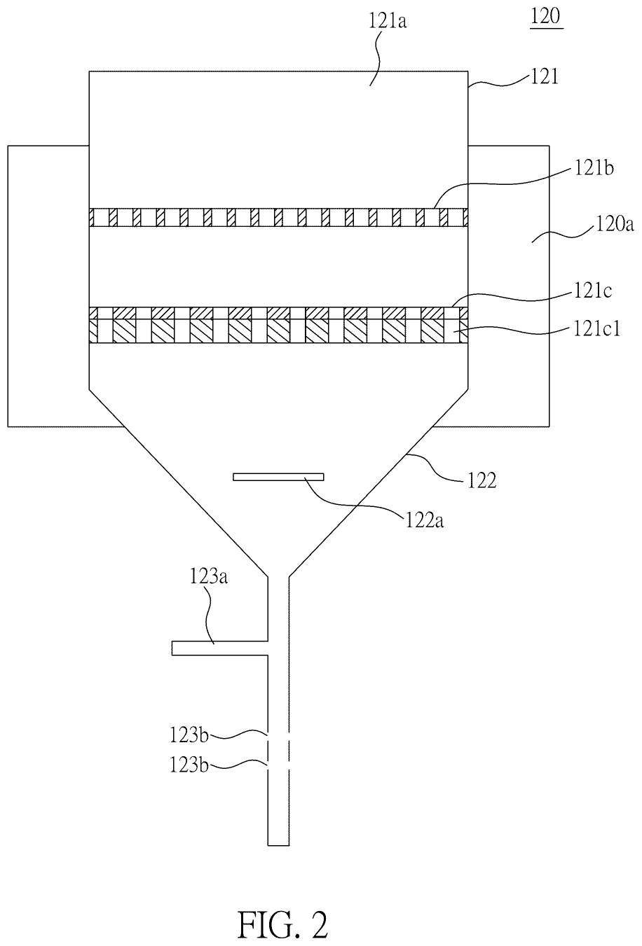

Please refer to FIGS. 1 and 2, where FIG. 1 illustrates a block diagram of a rework apparatus including an electronic component rework device of the invention; and FIG. 2 illustrates a schematic diagram of the electronic component rework device according to one embodiment of the invention. As shown in FIG. 1, a rework apparatus has a control circuit 110 coupled to an electronic component rework device 120, a feeding device 130, an actuating device 140, a pneumatic control device 150, and a robotic arm 160 for performing an electronic component rework procedure to deliver an electronic component for rework usage to a substrate 10; and as shown in FIG. 2, the electronic component rework device 120 has a body, which includes, from top to bottom, a feeding part 121, a tapering part 122, and a tubular part 123, where the feeding part 121 includes a feeding opening 121a, a sieve 121b, and a gate 121c from top to bottom, a stopper 122a is provided in the tapering part 122, and a pneumatic channel 123a is located on an upper side of an outer wall of the tubular part 123 and connected with an inner cavity of the tubular part 123.

In the feeding part 121, the feeding opening 121a is used to receive a plurality of electronic components supplied by the feeding device 130, where the electronic components can be copper pins; the sieve 121b is transversely disposed in the feeding part 121 for sieving out defective ones of the electronic components and contaminants attached to the electronic components; the gate 121c is located below the sieve 121b and transversely disposed in the feeding part 121, where when the gate 121c is in an open state, the electronic components are allowed to fall downward, and when the gate 121c is in a closed state, the electronic components are prevented from falling downward.

In the tapering part 122, the stopper 122a is used to prevent excessive accumulation of the electronic components at the inlet of the tubular part 123; and the pneumatic channel 123a is used to carry out a pneumatic control procedure, which includes: carrying out a negative pressure operation to draw a to-be-outputted electronic component of the electronic components into the tubular part 123 and hold it therein;

and when the tubular part 123 is moved to above a target contact pad of a substrate 10, terminating the negative pressure operation and then performing a blowing operation to provide a downward air flow to send downward the to-be-outputted electronic component and provide an upward air flow to prevent another one of the electronic components from moving downward through the tubular part 123.

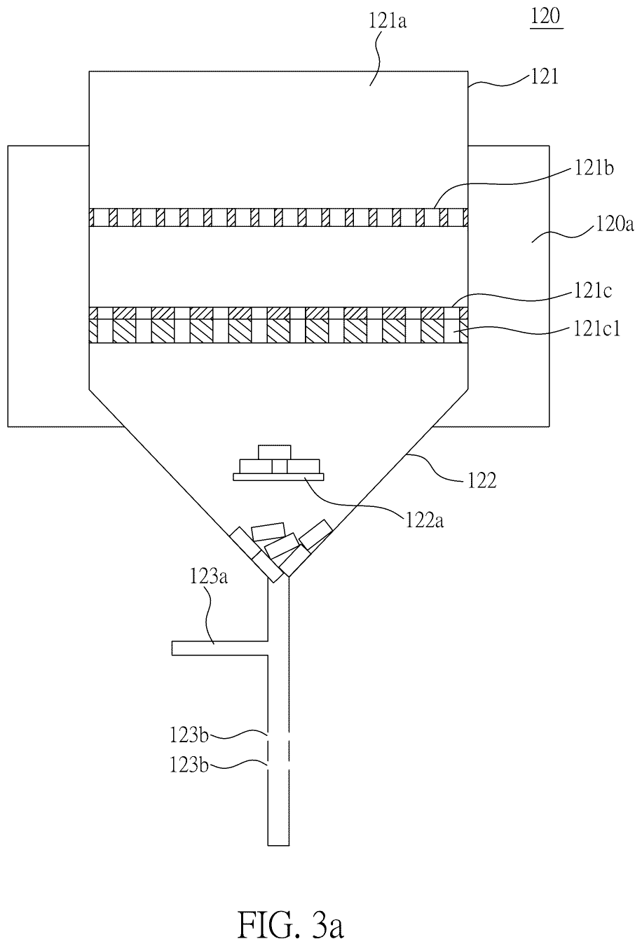

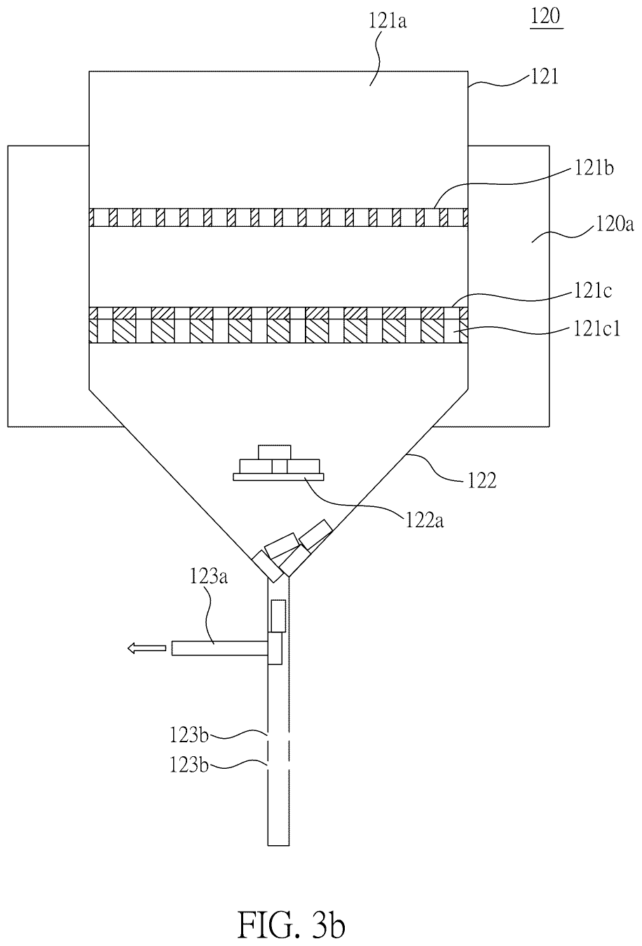

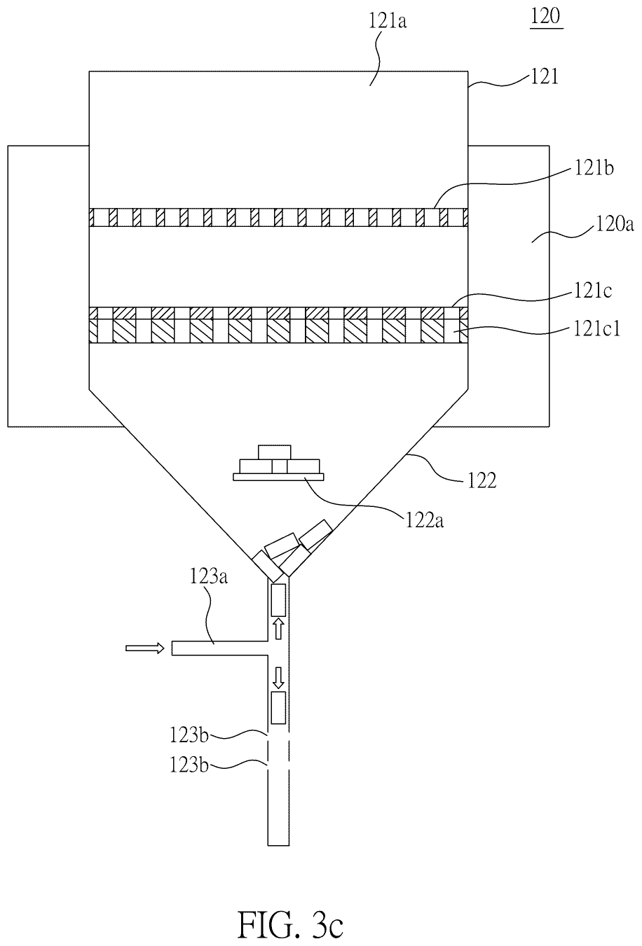

To be specific, the electronic component rework procedure includes:
(A) The control circuit 110 drives the feeding device 130 to feed a plurality of electronic components into the feeding opening 121a, where the electronic components can be copper pins.
(B) The control circuit 110 drives the actuating device 140 to open a plurality of holes 121c1 of the gate 121c to allow the electronic components to fall downward.
(C) The control circuit 110 drives the pneumatic control device 150 to perform a negative pressure operation on the pneumatic channel 123a to draw a to-be-outputted electronic component into the tubular part 123 and hold it in the tubular part 123. Please refer to FIGS. 3a and 3b, which illustrate scenarios before and after a negative pressure operation is performed on the pneumatic channel 123a. As shown in FIGS. 3a and 3b, the negative pressure operation on the pneumatic pressure channel 123a, which is performed by the pneumatic control device 150, draws one of the electronic elements 20 above the tubular part 123 into the tubular part 123 and holds it in place against a local area of the inner wall of the tubular part 123 that is around the pneumatic pressure channel 123a.
(D) The control circuit 110 drives the robotic arm 160 to move the tubular part 123 to above a target contact pad of the contact pads of the substrate 10, and then drives the air pressure control device 150 to terminate the negative pressure operation and then perform a blowing operation to provide a downward air flow to send out the to-be-outputted electronic component 20 and provide an upward air flow to prevent another electronic component 20 from moving downward from the upper end of the tubular part 123, or even empty the upper space of the tubular part 123. Please refer to FIG. 3c, which illustrates a scenario that a blowing operation is performed on the pneumatic channel after the negative pressure operation is terminated. As shown in FIG. 3c, a blowing operation, performed by the pneumatic pressure control device 150, is acting on the pneumatic pressure channel 123a to provide a downward air flow to send out the to-be-outputted electronic element 20, and provide an upward air flow to prevent another electronic element 20 from moving downward from the upper end of the tubular part 123.

In addition, the electronic component rework device 120 can be mounted to a vibration platform 120a, where the vibration platform 120a has an electrically controlled vibration device (not shown in the figure), and the procedure further includes: the control circuit 110 driving the electrically controlled vibration device to vibrate to expedite the electronic components 20 falling downward.

In addition, the openings 121c1 of the gate 121c can be opened or closed under the control of the actuating device 140.

In addition, the tubular part 123 has at least one pressure relief hole 123b formed near a lower end thereof for slowing down a falling speed of the to-be-outputted electronic component 20.

In addition, the distance from the stopper 122a to the inlet of the tubular part 123 can be two to four times the length of the electronic component 20.

In addition, the distance from the inlet of the tubular part 123 to the pneumatic channel 123a can be one to three times the length of the electronic component 20.

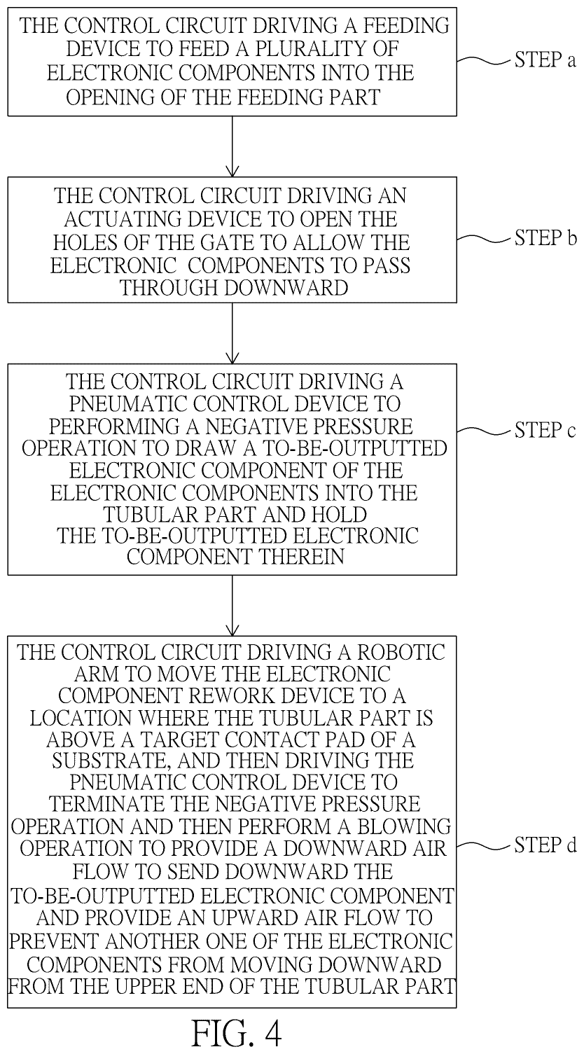

As can be seen from the above description, the invention discloses an electronic component rework method. Please refer to FIG. 4, which illustrates a flow chart of an electronic component rework method according to one embodiment of the invention, the method being realized by using a control circuit and an electronic component rework device. The electronic component rework device includes a feeding part, a tapering part and a tubular part, the feeding part having a feeding opening, a sieve and a gate from top to bottom, the tapering part being equipped with a stopper therein, and a pneumatic channel being located on an upper side of an outer wall of the tubular part and connected with an inner cavity of the tubular part. The method includes: the control circuit driving a feeding device to feed a plurality of electronic components into the opening of the feeding part (step a); the control circuit driving an actuating device to open the holes of the gate to allow the electronic components to pass through downward (step b); the control circuit driving a pneumatic control device to performing a negative pressure operation to draw a to-be-outputted electronic component of the electronic components into the tubular part and hold the to-be-outputted electronic component therein (step c); and the control circuit driving a robotic arm to move the electronic component rework device to a location where the tubular part is above a target contact pad of a substrate, and then driving the pneumatic control device to terminate the negative pressure operation and then perform a blowing operation to provide a downward air flow to send downward the to-be-outputted electronic component and provide an upward air flow to prevent another one of the electronic components from moving downward from the upper end of the tubular part (step d).

In the steps described above, the electronic component rework device can be mounted on a vibration platform having an electrically controlled vibration device, and the method can further include: the control circuit driving the electrically controlled vibration device to expedite the electronic components falling downward.

In addition, the openings of the gate are opened or closed under a control of the actuating device.

In addition, the tubular part can have at least one pressure relief hole formed near a lower end thereof for slowing down a falling speed of the to-be-outputted electronic component.

In addition, the electronic components can be copper pins.

In addition, the distance from the stopper to the inlet of the tubular part can be two to four times the length of the electronic component.

In addition, the distance from the inlet of the tubular part to the pneumatic channel can be one to three times the length of the electronic component.

As can be seen form the disclosure mentioned above, the invention provides the advantages as follows:
(1) The electronic component rework method of the invention can efficiently sift out an electronic component for rework usage from a plurality of electronic components by means of a sifting and guiding structure;
(2) The electronic component rework method of the invention can attract the electronic component for rework usage into a tubular part and hold it in place therein by a negative pressure operation, and after the tubular part is moved to above a target contact pad on a substrate, can use a blowing operation to push the electronic component for rework usage downward and prevent another electronic component from moving downward from the top of the tubular part at the same time;
(3) the electronic component rework device of the invention can efficiently sift out an electronic component for rework usage from a plurality of electronic components by means of the aforementioned electronic component rework method; and
(4) The electronic component rework device of the invention, by means of the aforementioned electronic component rework method, can attract the electronic component for rework usage into a tubular part and hold it in place therein by a negative pressure operation, and when the tubular part is moved to above a target contact pad on a substrate, can use a blowing operation to push the electronic component for rework usage downward and prevent another electronic component from moving downward from the top of the tubular part at the same time.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance over the conventional structure and further complies with the patent application requirements and is submitted to the Patent and Trademark Office for review and granting of the commensurate patent rights.

What is claimed is:

1. An electronic component rework device comprising:
a body having a feeding part, a tapering part, and a tubular part sequentially connected, the feeding part having a feeding opening for receiving a plurality of electronic components;
a sieve, which is transversely disposed in the feeding part for sifting out defective ones of the electronic components and contaminating material attached to the electronic components;
a gate, which is transversely disposed below the sieve in the feeding part for allowing the electronic components to fall downward when the gate is in an open state and preventing the electronic components from falling downward when the gate is in a closed state;
a stopper, which is provided in the tapering part to prevent excessive accumulation of the electronic components at an inlet of the tubular part; and
a pneumatic channel located on an upper side of an outer wall of the tubular part and connected with an inner cavity of the tubular part for carrying out a pneumatic control procedure, the pneumatic control procedure including: performing a negative pressure operation to draw a to-be-outputted electronic component of the electronic components into the tubular part and hold the to-be-outputted electronic component therein; and after the tubular part is moved to above a target contact pad of a substrate, driving the pneumatic control device to terminate the negative pressure operation and then perform a blowing operation to provide a downward air flow to send downward the to-be-outputted electronic component and provide an upward air flow to prevent another one of the electronic components from moving downward from the upper end of the tubular part.

2. The electronic component rework device as disclosed in claim 1, wherein the body is mounted on a vibration platform and the vibration platform has an electrically controlled vibration device.

3. The electronic component rework device as disclosed in claim 1, wherein the gate has a plurality of closable holes controlled to be open or closed by an actuating device.

4. The electronic component rework device as disclosed in claim 1, wherein the tubular part has at least one pressure relief hole formed near a lower end thereof for slowing down a falling speed of the to-be-outputted electronic component.

5. The electronic component rework device as disclosed in claim 1, wherein the electronic components are copper pins.

6. The electronic component rework device as disclosed in claim 1, wherein a distance from the stopper to the inlet of the tubular part is two to four times a length of the electronic component.

7. The electronic component rework device as disclosed in claim 1, wherein a distance from the inlet of the tubular part to the pneumatic channel is one to three times a length of the electronic component.

8. An electronic component rework method, which is realized by using a control circuit and an electronic component rework device, the electronic component rework device including a feeding part, a tapering part and a tubular part, the feeding part having a feeding opening, a sieve and a gate from top to bottom, the tapering part being equipped with a stopper therein, and a pneumatic channel being located on an upper side of an outer wall of the tubular part and connected with an inner cavity of the tubular part; the method including:
the control circuit driving a feeding device to feed a plurality of electronic components into the opening of the feeding part;
the control circuit driving an actuating device to open the holes of the gate to allow the electronic components to pass through downward;
the control circuit driving a pneumatic control device to performing a negative pressure operation to draw a to-be-outputted electronic component of the electronic components into the tubular part and hold the to-be-outputted electronic component therein; and
the control circuit driving a robotic arm to move the electronic component rework device to a location where the tubular part is above a target contact pad of a substrate, and then driving the pneumatic control device to terminate the negative pressure operation, and then perform a blowing operation to provide a downward air flow to send downward the to-be-outputted electronic component and provide an upward air flow to prevent another one of the electronic components from moving downward from the upper end of the tubular part.

9. The electronic component rework method as disclosed in claim 8, wherein the electronic component rework device is mounted on a vibration platform having an electrically controlled vibration device, and the method further includes: the control circuit driving the electrically controlled vibration device to expedite the electronic components falling downward.

10. The electronic component rework method as disclosed in claim 8, wherein the holes of the gate are controlled to be open or closed by the actuating device.

11. The electronic component rework method as disclosed in claim 8, wherein the tubular part has at least one pressure relief hole formed near a lower end thereof for slowing down a falling speed of the to-be-outputted electronic component.

12. The electronic component rework method as disclosed in claim 8, wherein the electronic components are copper pins.

13. The electronic component rework method as disclosed in claim 8, wherein a distance from the stopper to the inlet of the tubular part is two to four times a length of the electronic component.

14. The electronic component rework method as disclosed in claim 8, wherein a distance from the inlet of the tubular part to the pneumatic channel is one to three times a length of the electronic component.
